(19) United States
(12) Patent Application Publication
(10) Pub. No.: US 2026/0150637 A1
(43) Pub. Date: May 28, 2026

(54) ENGINEERED SUBSTRATE TECHNIQUES FOR GALLIUM NITRIDE DEVICES

(71) Applicants: James G. Fiorenza, Carlisle, MA (US); Leonard Shtargot, Campbell, CA (US); Daniel Piedra, Somerville, MA (US); Xiaowei Cai, Belmont, MA (US); Guanghai Ding, Bedford, MA (US); Jung-Han Hsia, Wilmington, MA (US); Chandan Joishi, Wilmington, MA (US)

(72) Inventors: James G. Fiorenza, Carlisle, MA (US); Leonard Shtargot, Campbell, CA (US); Daniel Piedra, Somerville, MA (US); Xiaowei Cai, Belmont, MA (US); Guanghai Ding, Bedford, MA (US); Jung-Han Hsia, Wilmington, MA (US); Chandan Joishi, Wilmington, MA (US)

(21) Appl. No.: 19/400,811

(22) Filed: Nov. 25, 2025

Related U.S. Application Data
(60) Provisional application No. 63/725,354, filed on Nov. 26, 2024.
(60) Provisional application No. 63/737,577, filed on Dec. 20, 2024.
(60) Provisional application No. 63/891,822, filed on Oct. 1, 2025.

(51) Int. Cl. H10P 90/00; H10D 30/47; H10D 64/00; H10D 86/00; H10D 86/01

(52) U.S. Cl. CPC H10P 90/1916; H10D 30/475; H10D 86/01; H10D 86/201; H10D 64/112

(57) ABSTRACT

Various engineered substrate techniques for gallium nitride devices are described that address limitations of conventional substrate approaches. For example, various techniques are described for implementing silicon carbide-on-poly-aluminum nitride (poly-AlN) and sapphire-on-poly-AlN engineered substrates using smart cut processes, hydrogen implantation and exfoliation, and advanced field management approaches to improve device performance while maintaining cost-effectiveness. The engineered substrates described provide the lattice matching and thermal benefits of silicon carbide or sapphire surfaces, for example, while utilizing the CTE matching and cost advantages of poly-AlN handle wafers. In addition, techniques are described for manufacturing high-voltage GaN devices with improved reliability, reduced dislocation density, enhanced thermal performance, and effective backside field management that may be difficult to achieve with conventional substrate approaches, while maintaining compatibility with established device fabrication processes and enabling monolithic integration of multiple device types on the same platform.

### CLAIM OF PRIORITY

This application claims priority to U.S. Provisional Application No. 63/891,822, titled “BURIED CHANNEL AIGaN BUFFER TRANSISTORS” to James G. Fiorenza et al., filed Oct. 1, 2025, U.S. Provisional Application No. 63/737,577, titled “AlGaN COMPOUND SEMICONDUCTOR DEVICES” to James G. Fiorenza et al., filed Dec. 20, 2024, and U.S. Provisional Application No. 63/725,354, titled “BURIED CHANNEL AlGaN BUFFER TRANSISTORS” to James G. Fiorenza et al., filed Nov. 26, 2024, which are hereby incorporated by reference herein in their entireties.

### FIELD OF THE DISCLOSURE

This document pertains generally, but not by way of limitation, to semiconductor devices and processing, and more particularly but not by way of limitation, to semiconductor devices with engineered substrates.

### BACKGROUND

Gallium nitride (GaN) based semiconductors offer several advantages over other semiconductors as the material of choice for fabricating the next generation of transistors, or semiconductor devices, for use in both high voltage and high frequency applications. GaN based semiconductors, for example, have a wide bandgap that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification systems. GaN based semiconductors, however, are typically used to fabricate depletion mode (or normally on) devices, which may have limited use in many of these systems, such as due to the added circuit complexity required to support such devices.

### SUMMARY OF THE DISCLOSURE

This disclosure describes various engineered substrate techniques for gallium nitride devices that address limitations of conventional substrate approaches. For example, various techniques are described for implementing silicon carbide-on-poly-aluminum nitride (poly-AlN) and sapphire-on-poly-AlN engineered substrates using smart cut processes, hydrogen implantation and exfoliation, and advanced field management approaches to improve device performance while maintaining cost-effectiveness. The engineered substrates described provide the lattice matching and thermal benefits of silicon carbide or sapphire surfaces, for example, while utilizing the CTE matching and cost advantages of poly-AlN handle wafers. In addition, techniques are described for manufacturing high-voltage GaN devices with improved reliability, reduced dislocation density, enhanced thermal performance, and effective backside field management that may be difficult to achieve with conventional substrate approaches, while maintaining compatibility with established device fabrication processes and enabling monolithic integration of multiple device types on the same platform.

In some aspects, this disclosure is directed to a method of forming a semiconductor device, comprising: implanting p-type dopants into a donor wafer and activating the p-type dopants to form a p-type doped region in the donor wafer; implanting hydrogen adjacent to a top surface of the donor wafer; bonding the donor wafer to a poly-aluminum nitride (poly-AlN) or semi-insulating silicon carbide (SiC) handle wafer with one or more dielectric layers disposed therebetween to form a bonded structure, wherein the implanted hydrogen is adjacent to the one or more dielectric layers; and annealing the bonded structure to remove a portion of the donor wafer, thereby forming a semiconductor layer disposed over the one or more dielectric layers.

In some aspects, this disclosure is directed to a semiconductor device comprising: an engineered substrate comprising: a poly-aluminum nitride (poly-AlN) or semi-insulating silicon carbide (SiC) handle wafer; one or more dielectric layers disposed over the handle wafer; and a semiconductor layer disposed over the one or more dielectric layers, wherein the semiconductor layer includes hydrogen implanted into a donor wafer, wherein the semiconductor layer is formed from a donor wafer bonded to the handle wafer, and wherein the donor wafer comprises silicon carbide (SiC) or sapphire; and a transistor device formed over the engineered substrate, the transistor device comprising an aluminum nitride (AlN) buffer layer, wherein a coefficient of thermal expansion (CTE) of the handle wafer is similar to a CTE of the AlN buffer layer to prevent wafer bowing during growth of the AlN buffer layer.

In some aspects, this disclosure is directed to a method of forming a semiconductor device, comprising: implanting p-type dopants into a donor wafer and activating the p-type dopants to form a p-type doped region in the donor wafer; implanting hydrogen adjacent to a top surface of the donor wafer; bonding the donor wafer to a poly-aluminum nitride (poly-AlN) or semi-insulating silicon carbide (SiC) handle wafer with one or more dielectric layers disposed therebetween to form a bonded structure, wherein the implanted hydrogen is adjacent to the one or more dielectric layers; annealing the bonded structure to remove a portion of the donor wafer, thereby forming a semiconductor layer disposed over the one or more dielectric layers; and forming a transistor device over the semiconductor layer, the transistor device comprising an aluminum nitride (AlN) buffer layer, wherein the transistor device includes a two-dimensional electron gas channel, and wherein a coefficient of thermal expansion of the handle wafer is similar to a coefficient of thermal expansion of the AlN buffer layer to prevent wafer bowing during growth of the AlN buffer layer.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 depicts a flow diagram of an example of a method of forming a semiconductor device.

FIG. 2 depicts a flow diagram of another example of a method of forming a semiconductor device, in accordance with this disclosure.

FIG. 3 depicts an example of a transistor device formed over a semiconductor device, in accordance with this disclosure.

FIG. 4 depicts an example of a semiconductor device in accordance with this disclosure.

FIG. 5 depicts another example of a transistor device formed over a semiconductor device, in accordance with this disclosure.

FIG. 6 illustrates an aspect of the subject matter in accordance with one embodiment.

FIG. 7 depicts an example of two transistor devices formed over a semiconductor device, in accordance with this disclosure.

FIG. 8 depicts another example of a semiconductor device in accordance with this disclosure.

FIG. 9 depicts another example of two transistor devices formed over a semiconductor device, in accordance with this disclosure.

FIG. 10 is a flow diagram of an example of a method of forming a semiconductor device, in accordance with this disclosure.

### DETAILED DESCRIPTION

The present inventors have recognized an issue with existing gallium nitride (GaN) power transistor devices fabricated on conventional substrates. Although GaN transistor devices demonstrate superior electrical performance compared to silicon transistor devices, conventional substrate approaches may limit the reliability, thermal performance, and voltage capabilities of GaN power transistor devices. Conventional GaN transistor devices are typically fabricated on silicon substrates, which may suffer from lattice mismatch and coefficient of thermal expansion (CTE) mismatch with GaN epitaxial layers. This mismatch may result in dislocation densities that may be much higher than achievable with better-matched substrates, leading to reliability issues and limiting the performance potential of GaN power transistor devices. Although silicon carbide substrates offer better lattice matching and thermal properties, the cost of silicon carbide wafers remains expensive for power switching applications.

The present inventors have also recognized that conventional substrate approaches face competing requirements that limit device optimization. For high-voltage applications, it may be desirable to have thin GaN epitaxial layers to reduce costs and improve device performance. However, conventional approaches are limited to thick GaN epitaxial layers for high-voltage applications. Besides, these approaches may struggle to effectively implement advanced field management approaches, for example, backside field management techniques, due to substrate limitations, which may restrict the achievable breakdown voltage and field management capabilities. Furthermore, existing substrate technologies do not adequately address the thermal management requirements of high-power density GaN transistor devices, where efficient heat removal may be important for reliable operation. Additionally, conventional engineered substrates incorporating thin silicon layers may create problematic electric field termination points that require thicker epitaxial layers to manage field distributions effectively.

This disclosure describes various engineered substrate techniques for gallium nitride devices that address limitations of conventional substrate approaches. For example, various techniques are described for implementing silicon carbide-on-poly-aluminum nitride (poly-AlN) and sapphire-on-poly-AlN engineered substrates using smart cut processes, hydrogen implantation and exfoliation, and advanced field management approaches to improve device performance while maintaining cost-effectiveness. The engineered substrates described provide the lattice matching and thermal benefits of silicon carbide or sapphire surfaces, for example, while utilizing the CTE matching and cost advantages of poly-AlN handle wafers. In addition, techniques are described for manufacturing high-voltage GaN devices with improved reliability, reduced dislocation density, enhanced thermal performance, and effective backside field management that may be difficult to achieve with conventional substrate approaches, while maintaining compatibility with established device fabrication processes and enabling monolithic integration of multiple device types on the same platform.

As used in this disclosure, a GaN-based compound semiconductor material may include a chemical compound of elements including Ga, N and one or more elements from different groups in the periodic table. Such chemical compounds may include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. In an example, a semiconductor device may be fabricated from GaN and aluminum indium gallium nitride (AlInGaN).

Heterostructures described herein may be formed as AlN/GaN/AlN hetero-structures, InAlN/GaN heterostructures, AlGaN/GaN heterostructures, or heterostructures formed from other combinations of group 13 and group 15 elements. These heterostructures may form a two-dimensional electron gas (2DEG) at the interface of the compound semiconductors that form the heterostructure, such as the interface of GaN and AlGaN. The 2DEG may form a conductive channel of electrons that may be controllably depleted, such as by an electric field formed by a buried layer of p-type material disposed below the channel. The conductive channel of electrons may also be controllably enhanced, such as by an electric field formed by a gate terminal disposed above the channel to control a current through the semiconductor device. Semiconductor devices formed using such conductive channels may include high electron mobility transistors.

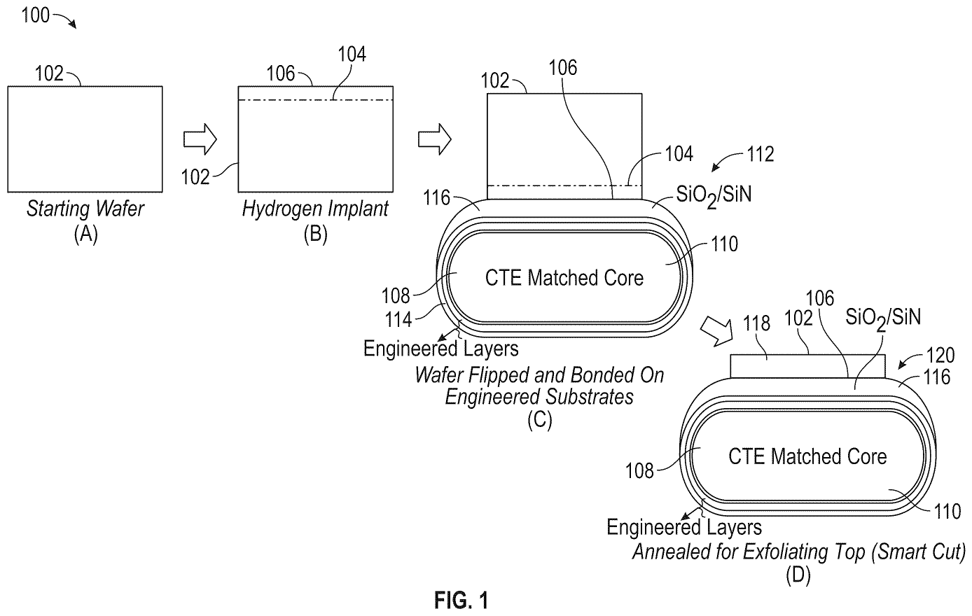

FIG. 1 depicts a flow diagram of an example of a method 100 of forming a semiconductor device. In particular, FIG. 1 depicts forming a substrate of a semiconductor device. The images are cross-sectional views. Initially, at (A), a donor wafer 102 (or “starting wafer”), such as a silicon carbide (SiC) or sapphire wafer, is provided.

Then, at (B), the method 100 includes implanting hydrogen 104 adjacent to a top surface 106 of the donor wafer 102. In some examples, the hydrogen 104 has an implantation dose of about 5E16 to 1E17 species per centimeter squared. In some examples, the hydrogen 104 is implanted at a depth of 50-3000 nanometers (nm).

At (C), the method 100 includes flipping the donor wafer 102, and bonding the top surface 106 of the donor wafer 102 to a handle wafer 108, such as a poly-aluminum nitride (poly-AlN) or semi-insulating silicon carbide (SiC) handle wafer (or “engineered substrate”), to form a bonded structure 112. Semi-insulating wafer refers to a substrate characterized by a high electrical resistivity, typically greater than about 1E6 ohms times centimeter (cm). The semi-insulating properties substantially reduce parasitic conduction through the substrate, thereby providing electrical isolation for overlying device layers. The handle wafer 108 includes a core 110 whose coefficient of thermal expansion (CTE) is matched to a buffer layer, such as a GaN buffer layer, of a transistor device formed over the semiconductor device.

The handle wafer 108 includes one or more engineered layers 114. The engineered layer(s) are dielectric layers, such as silicon nitride (SiN) and/or silicon dioxide (SiO₂) alone or in combination, that are disposed between the top surface 106 and the handle wafer 108. The engineered layers 114 seal the handle wafer 108 and prevent contaminants, such as yttria (Y₂O₃), from escaping the CTE-matched core 110. The implanted hydrogen 104 is adjacent to the dielectric layers 116.

Finally, at (D), the bonded structure 112 is annealed to remove, e.g., exfoliate, a portion of the donor wafer 102, thereby forming a semiconductor layer 118 disposed over the one or more dielectric layers 116 to create a semiconductor device 120. The hydrogen implantation creates a weakened portion within the donor wafer 102. When the bonded structure 112 is annealed, the material above the hydrogen 104 implant region separates and may be removed, leaving behind only a thin surface layer, for example, 50-3000 nm, of the donor wafer 102.

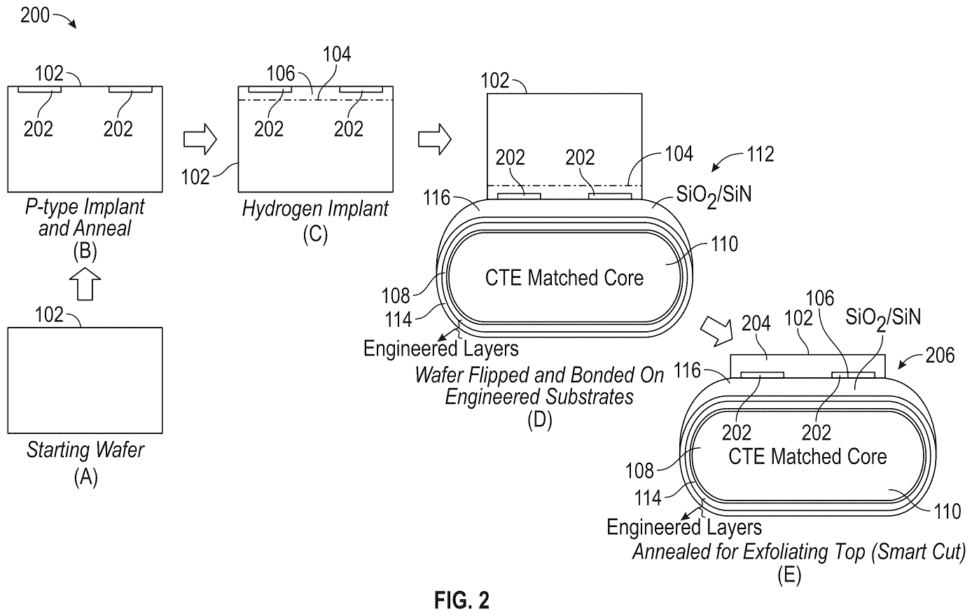

FIG. 2 depicts a flow diagram of another example of a method 200 of forming a semiconductor device, in accordance with this disclosure. In particular, FIG. 2 depicts forming a substrate of a semiconductor device. Some of the steps are similar to those described above with respect to FIG. 1 and, as such, similar reference numbers are used.

Initially, at (A), a donor wafer 102 (or “starting wafer”), such as a silicon carbide (SiC), is provided. Then, at (B), the method 200 includes implanting p-type dopants, such as aluminum, boron, gallium, or magnesium, into the donor wafer 102 and activating the p-type dopants, such as by high-temperature activation (e.g., around 1700° C.), to form a p-type doped regions 202 in the donor wafer 102.

Then, at (C), the method 200 includes implanting hydrogen 104 adjacent to a top surface 106 of the donor wafer 102. In some examples, the hydrogen 104 has an implantation dose of about 5E16 to 1E17 species per centimeter squared. In some examples, the hydrogen 104 is implanted at a depth of 50-3000 nm. At (D), the method 200 includes flipping the donor wafer 102, and bonding the top surface 106 of the donor wafer 102 to a handle wafer 108, such as a poly-aluminum nitride (poly-AlN) or semi-insulating silicon carbide (SiC) handle wafer, to form a bonded structure 112. The handle wafer 108 includes a core 110 whose coefficient of thermal expansion (CTE) is matched or substantially similar (within 15%) to a buffer layer, such as a GaN buffer layer, of a transistor device formed over the semiconductor device.

The handle wafer 108 includes one or more engineered layers 114. The engineered layer(s) are dielectric layers, such as silicon nitride (SiN) and/or silicon dioxide (SiO₂) alone or in combination, that are disposed between the top surface 106 and the handle wafer 108. The engineered layers 114 seal the handle wafer 108 and prevent contaminants, such as yttria (Y₂O₃), from escaping the CTE-matched core 110. The implanted hydrogen 104 is adjacent to the dielectric layers 116.

Finally, at (E), the bonded structure 112 is annealed to remove, e.g., exfoliate, a portion of the donor wafer 102, thereby forming a semiconductor layer 204 disposed over dielectric layers 116 to create a semiconductor device 206. The hydrogen implantation creates a weakened portion within the donor wafer 102. When the bonded structure 112 is annealed, the material above the hydrogen 104 implant region separates and may be removed, leaving behind only a thin surface layer of the donor wafer 102.

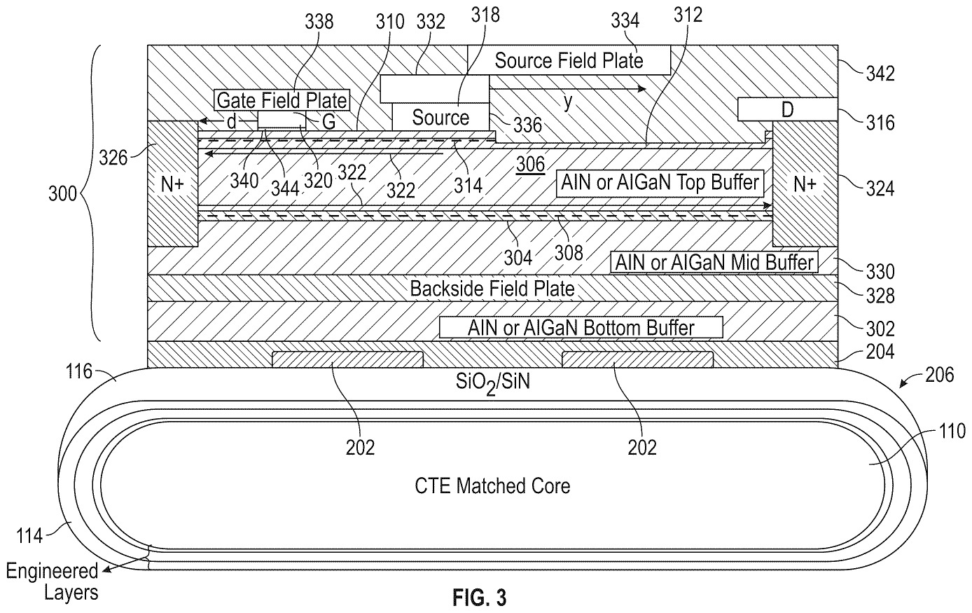

FIG. 3 depicts an example of a transistor device formed over a semiconductor device, in accordance with this disclosure. FIG. 3 is a cross-sectional view. In the example shown, the transistor device 300 is formed over the semiconductor device 206 of FIG. 2.

The transistor device 300 includes a bottom buffer layer 302, such as aluminum nitride (AlN) or aluminum gallium nitride (AlGaN), that is formed over the semiconductor device 206. The CTE of the core 110 of the handle wafer 108 of the semiconductor device 206 is similar to the CTE material of the bottom buffer layer 302 to prevent wafer bowing during growth of the buffer layer.

A first semiconductor material layer 304, e.g., gallium nitride (GaN), is formed over the bottom buffer layer 302. A second semiconductor material layer 306, e.g., a top buffer layer, is formed over the first semiconductor material layer 304 to form a first compound semiconductor heterostructure. The second semiconductor material layer 306 may include AlN or AlGaN.

The first compound semiconductor heterostructure includes a buried first two-dimensional electron gas (2DEG) 308, where the buried first 2DEG channel 308 is more electrically conductive than either the first semiconductor material layer 304 or the second semiconductor material layer 306. The buried first 2DEG channel 308 is located at the interface of the first semiconductor material layer 304 and the second semiconductor material layer 306. In some examples, the transistor device 300 includes a single buried first 2DEG channel, as shown in FIG. 3. In other examples, the transistor device 300 includes two or more buried first 2DEG channels.

The transistor device 300 further includes a third semiconductor material layer 310 formed over a fourth semiconductor material layer 312 to form a second compound semiconductor heterostructure, which includes a topside second 2DEG channel 314, where the topside second 2DEG channel 314 is more electrically conductive than either the third semiconductor material layer 310 or the fourth semiconductor material layer 312. The topside second 2DEG channel 314 is located at the interface of the third semiconductor material layer 310 and the fourth semiconductor material layer 312. The fourth semiconductor material layer 312 may include GaN, and the third semiconductor material layer 310 may include AlN or AlGaN. The fourth semiconductor material layer 312 is formed over the second semiconductor material layer 306, e.g., the top buffer layer.

The transistor device 300 further includes a drain electrode 316 electrically coupled with the buried first 2DEG channel 308, a source electrode 318 electrically coupled with the topside second 2DEG channel 314, and a gate electrode 320, e.g., a p-GaN gate, electrically coupled with the third semiconductor material layer 310. In this way, a standard p-GaN enhancement mode transistor device may be made by inserting a p-GaN layer 344 in between the third semiconductor material layer 112 and the gate 122. In some examples, a passivation layer 342 is formed above the third semiconductor material layer 310.

The transistor device 300 further includes a first conductive material 324 that extends vertically from the drain electrode 316 to the bottom buffer layer 302 and electrically couples the buried first 2DEG channel 308 and the drain electrode 316. In the example shown, the first conductive material 324 is electrically coupled with and extends below the drain electrode 316. The transistor device 300 further includes a second conductive material 326 that extends vertically between and electrically couples the buried first 2DEG channel 308 and the topside second 2DEG channel 314. In some examples, the second conductive material 326 is laterally offset from the gate electrode 320 in a plane parallel with the third semiconductor material layer 310 by at least a distance d along a plane parallel to the third semiconductor material layer 310 and on a side of the gate electrode 320 opposite the source electrode 318. In some examples, the first conductive material 324 and the second conductive material 326 include N+ GaN.

A current path 322 is shown in FIG. 3. Current flows leftward in the topside second 2DEG channel 314 from the source electrode 318 to the second conductive material 326, downward through the second conductive material 326 to the buried first 2DEG channel 308, then rightward through the buried first 2DEG channel 308 to the first conductive material 324, and then upward through the first conductive material 324 to the drain electrode 316.

In the example shown, the transistor device 300 includes p-type doped regions 202 that are configured to function as backside field plates, such as when connected to the source electrode 318. In addition, the transistor device 300 includes a backside field plate 328 formed between the semiconductor device 206 and the buried first 2DEG channel 308. In some examples, the backside field plate 328 is formed with polarization doped p-type GaN. The backside field plate 328 is connected to the source electrode 120.

The bottom buffer layer 302 is formed first, e.g., grown, and then the backside field plate 328 is formed over the bottom buffer layer 302. Then, a middle buffer layer 330 is formed, e.g., grown, between the backside field plate 328 and the buried first 2DEG channel 308. In some examples, the middle buffer layer 330 includes AlN or AlGaN. Eventually, the second semiconductor material layer 306, e.g., the top buffer layer, is formed, e.g., grown, between the buried first 2DEG channel 308 and the topside second 2DEG channel 314. In some examples, top buffer layer includes AlN or AlGaN. In some examples, a high temperature, such as greater than 1200 degrees Celsius, a Metal-Organic Chemical Vapor Deposition (MOCVD) reactor may be used to grow AlN and achieve high quality, smooth, and low dislocation films.

In addition, the transistor device 300 may include a first source field plate 332 in electrical contact with and formed above the source electrode 318. The buried first 2DEG channel 308 may formed at a specific distance beneath the source electrode 318 so that the buried first 2DEG channel 308 pinches off at the correct drain voltage for optimum field management.

The transistor device 300 may further include a second source field plate 334 in electrical contact with and formed above the first source field plate 332. In some examples, the second source field plate 334 extends laterally beyond an end 336 of the source electrode 318 by at least a distance Y along a plane parallel to the third semiconductor material layer 310 and on a side of the source electrode 318 opposite the gate electrode 320.

In addition, the transistor device 300 may include a gate field plate 338 in electrical contact with the gate electrode 320. The gate field plate 338 extends laterally in a plane parallel with the third semiconductor material layer 310 beyond an end 340 of the gate electrode 320 by at least some distance along a plane parallel to the third semiconductor material layer 310 and on a side of the gate electrode 320 opposite the source electrode 318.

In some examples, the transistor device 300 formed over the semiconductor layer 204 is a high-voltage GaN or AlGaN transistor rated for 600 V-3000 V, such as a field-effect transistor, where the drain fields of the transistor device 300 penetrate through the semiconductor layer to improve field handling.

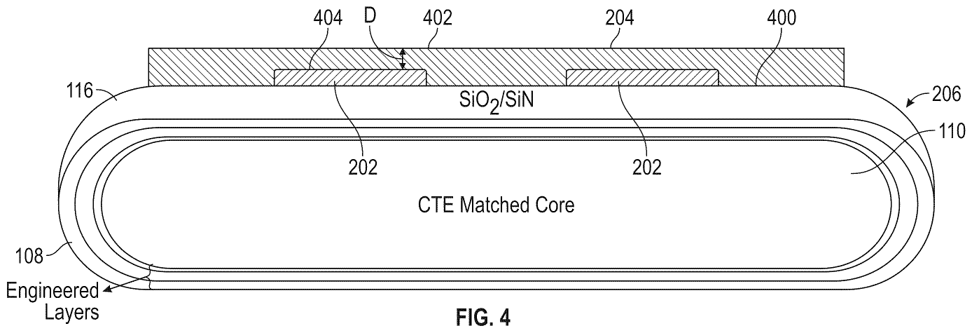

FIG. 4 depicts an example of a semiconductor device 206. FIG. 4 is a cross-sectional view. In accordance with this disclosure, the p-type dopants of the one or more p-type doped regions 202 are positioned so as to not reach a top surface 402 of the semiconductor layer 204 after removal, e.g., exfoliation, of the excess donor wafer 102. That is, the p-type implant is optimized using optimal conditions for implant dose, implant energy and implant activation annealing temperature, to not reach the top surface 402 of donor wafer, e.g., donor wafer 102 of FIG. 1, after the donor wafer 102 is flipped and bonded to the poly-AlN engineered substrate, namely handle wafer 108. For example, there is a distance D between a top 404 of the p-type doped region 202 and the top surface 402 of the semiconductor layer 204. The p-type doped region 202 is spatially separated from top surface 402 where the epitaxial growth is carried out. This separation substantially reduces the risk of dopant or impurity diffusion from the p-type doped region 202 into the epitaxial layer, thereby preserving the purity of the grown material. As a result, improved crystal quality may be achieved, which may lower dislocation density, enhance surface morphology, and improve overall device reliability and performance.

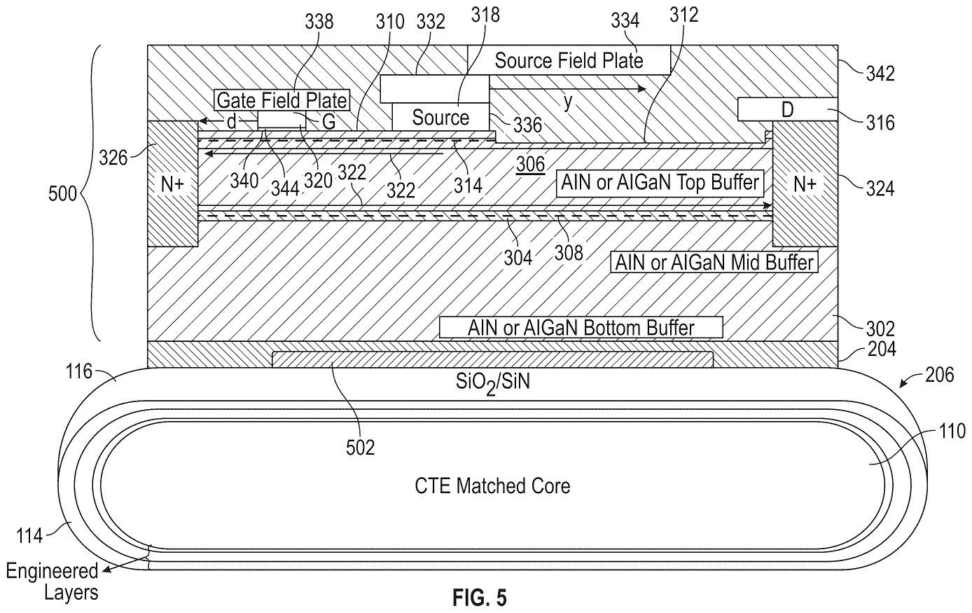

FIG. 5 depicts another example of a transistor device formed over a semiconductor device, in accordance with this disclosure. FIG. 5 is a cross-sectional view. The transistor device 500 is formed over the semiconductor device 206 and includes some components that are similar to components in the transistor device 300 of FIG. 3. Similar components use similar reference numbers and, for brevity, will not be described in detail again.

In FIG. 5, the p-type doped regions 202 in FIG. 2 are joined in the semiconductor layer 204 to form a backside superjunction device, such as a superjunction backside field plate 502. The superjunction backside field plate 202 is connected to the source electrode 336.

The superjunction backside field plate 502 is a p-type implanted region in the semiconductor layer 204 that is configured to operate as a superjunction. A superjunction is configured to deplete during normal operation of the transistor device 500. A density of p-type dopants in the p-type implanted region, namely the superjunction backside field plate 502, is substantially matched to a density of the electrons in the 2-D electron gas of the buried first 2DEG channel 308.

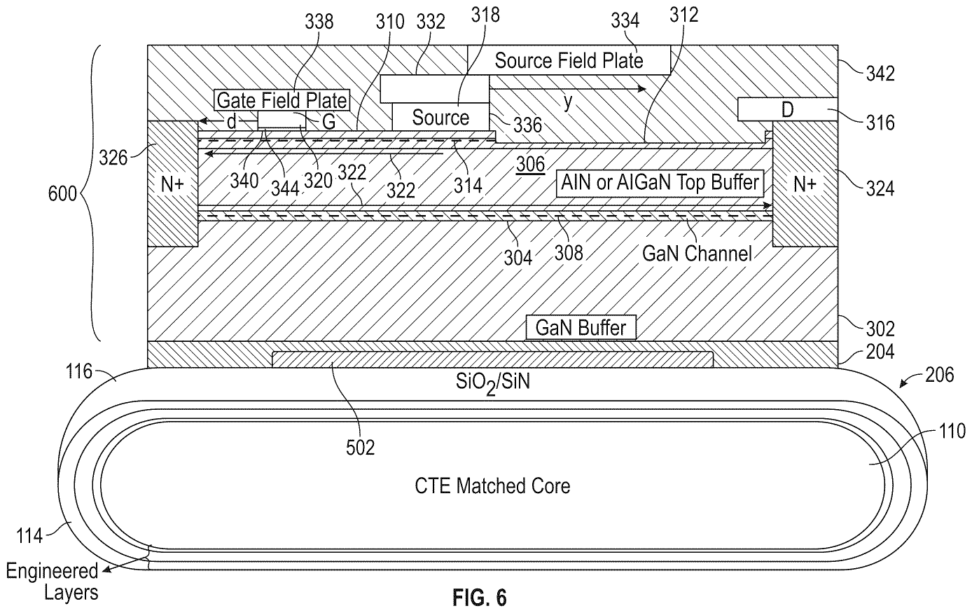

FIG. 6 depicts another example of a transistor device formed over a semiconductor device, in accordance with this disclosure. FIG. 6 is a cross-sectional view. The transistor device 600 is formed over the semiconductor device 206 and includes some components that are similar to components in the transistor device 300 of FIG. 3. Similar components use similar reference numbers and, for brevity, will not be described in detail again.

In the transistor device 600, the bottom buffer layer 302 is a gallium nitride buffer layer formed over the semiconductor layer 204. The GaN buffer layer is a thin buffer layer, such as in the range of about 100 nm to 2 μm, which may help improve heat spreading compared to AlGaN buffer layers. In some examples, the GaN buffer layer is a p-type GaN buffer layer.

In addition, a superjunction backside field plate 502 is formed in the semiconductor layer 204, as described above with respect to FIG. 5. A superjunction is configured to deplete during normal operation of the transistor device 600. A density of p-type dopants in the p-type implanted region, namely the superjunction backside field plate 502, is substantially matched to a density of the electrons in the 2-D electron gas of the buried first 2DEG channel 308.

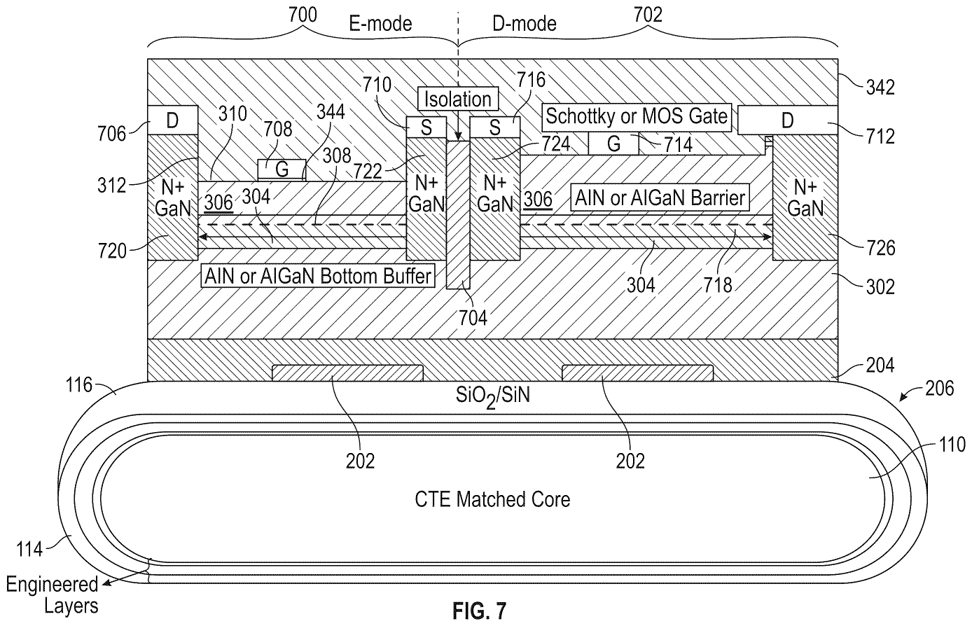

FIG. 7 depicts an example of two transistor devices formed over a semiconductor device, in accordance with this disclosure. FIG. 7 is a cross-sectional view. A first transistor device 700 and a second transistor device 702 are formed laterally adjacent one another over the semiconductor layer 204 and monolithically integrated over the semiconductor device 206. In the example shown, the first transistor device 700 and the second transistor device 702 share the bottom buffer layer 302 and are laterally separated by an isolation barrier 704, formed by ion implantation of species such as nitrogen. In some examples, the first transistor device 700 is an enhancement-mode device and the second transistor device 702 is a depletion-mode device.

The first transistor device 700 may include a drain electrode 706, a gate electrode 708, e.g., a p-GaN gate, and a source electrode 710. Like the transistor device 300 of FIG. 3, for example, the first transistor device 700 may include one or more buried 2DEG channels 308. The first transistor device 700 further includes a first conductive material 700 that extends vertically from the drain electrode 706 to the bottom buffer layer 302 and electrically couples the buried first 2DEG channel 308 and the drain electrode 706. In the example shown, the first conductive material 324 is electrically coupled with and extends below the drain electrode 706. The transistor device 700 further includes a second conductive material 722 that is electrically coupled with and extends below the source electrode 710. In some examples, the first conductive material 324 and the second conductive material 326 include N+ GaN.

The second transistor device 702 may include a drain electrode 712, a gate electrode 714, e.g., a Schottky or metal-oxide-semiconductor (MOS) gate, and a source electrode 716. The second transistor device 702 may include one or more 2DEG channels 718 formed at the interface between the first semiconductor material layer 304 and the second semiconductor material layer 306.

The second transistor device 702 further includes a conductive material 726 that extends vertically from the drain electrode 712 to the bottom buffer layer 302 and electrically couples the 2DEG channel 718 and the drain electrode 712. In the example shown, the conductive material 726 is electrically coupled with and extends below the drain electrode 712. The second transistor device 702 further includes a conductive material 724 that extends vertically between and electrically couples the 2DEG channel 718 and the source electrode 716. In some examples, the conductive material 724 and the conductive material 626 include N+ GaN. The techniques of FIG. 7 allow high-side and low-side switches to be developed on the same die, which are enabled by the excellent electrical isolation properties of semi-insulating SiC or sapphire on poly-AlN engineered substrates, thereby eliminating the need for complex isolation techniques.

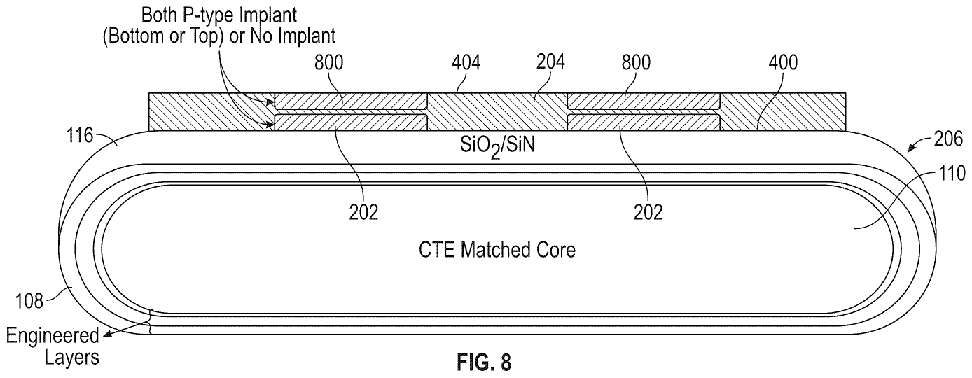

FIG. 8 depicts another example of a semiconductor device 206. FIG. 8 is a cross-sectional view. In accordance with this disclosure, the interface 400 between the semiconductor layer 204 and the one or more dielectric layers 116 may be modified to reduce the high density of interface traps at the interface due to dangling bonds and oxygen vacancies, e.g., annealed, to optimize the SiC/SiO₂ interface 400 on the semiconductor device 206, e.g., a poly-AlN engineered substrate. The interface modification may be performed using plasma nitridation, plasma oxidation, or annealing in nitric oxide (NO) or nitrous oxide (N₂O) to reduce trapping at the backside and improve device performance and reliability.

In some examples, the p-type doped regions may be formed adjacent to the interface 400 between the dielectric layers 116 and the semiconductor layer 204, such as shown with p-type doped regions 202. In other examples, the p-type doped regions may be formed adjacent to the top 404 of the semiconductor layer 204, such as shown with p-type doped region 800.

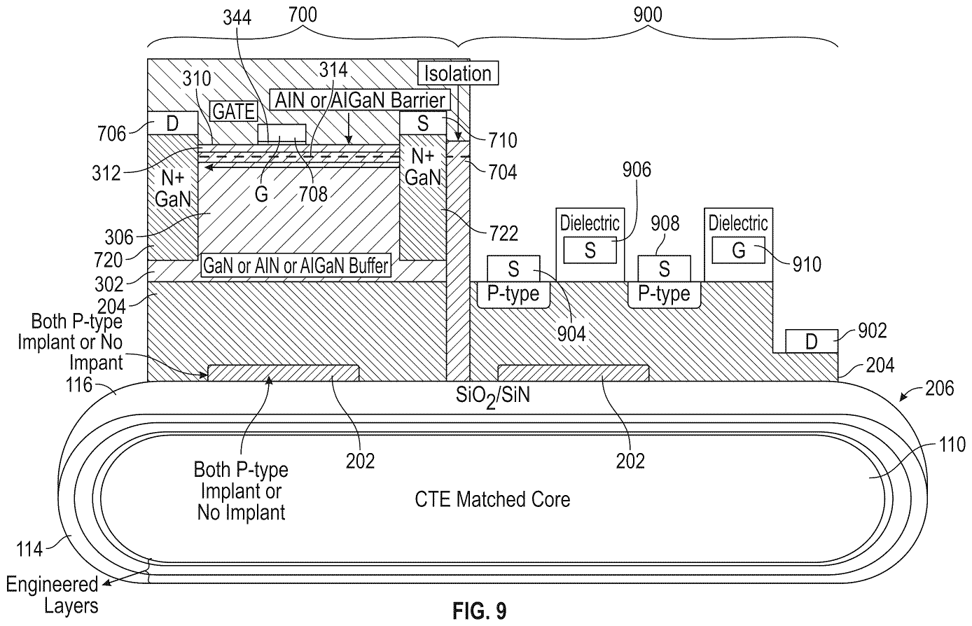

FIG. 9 depicts another example of two transistor devices formed over a semiconductor device, in accordance with this disclosure. FIG. 9 is a cross-sectional view. A first transistor device 700 and a second transistor device 900 are formed laterally adjacent one another over the semiconductor layer 204 and monolithically integrated over the semiconductor device 206. In the example shown, the first transistor device 700 is an example of a GaN device and the second transistor device 900 is an example of a SiC device.

In the example shown, the first transistor device 700 and the second transistor device 900 share the semiconductor layer 204 and are laterally separated by an isolation barrier 704, formed by ion implantation of species such as nitrogen. In some examples, the first transistor device 700 is an enhancement-mode device and the second transistor device 702 is a depletion-mode device.

The first transistor device 700 may include a drain electrode 706, a gate electrode 708, e.g., a p-GaN gate, and a source electrode 710. Like the transistor device 300 of FIG. 3, for example, the first transistor device 700 may include one or more 2DEG channels, such as one or more topside second 2DEG channels 314.

The second transistor device 900 may include a drain electrode 902, a first source electrode 904, a first gate electrode 906, a second source electrode 908, and a second gate electrode 910. The second transistor device 900 shown in FIG. 9 does not include any 2DEG channels. In some examples, the second transistor device 900 is a high-voltage device, with voltage ratings from about 650 V-3000 V. In some examples, the first transistor device 700 is a low-voltage device, with ratings below about 650 V.

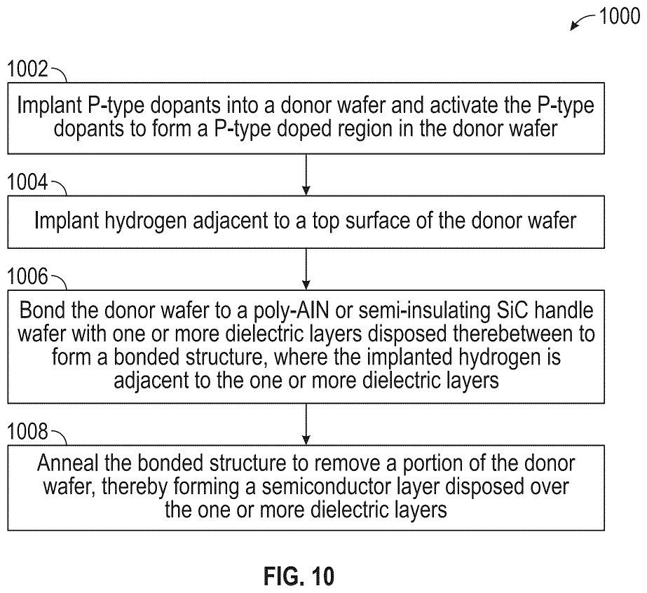

FIG. 10 is a flow diagram of an example of a method 1000 of forming a semiconductor device, in accordance with this disclosure. At block 1002, the method 1000 includes implanting p-type dopants into a donor wafer and activating the p-type dopants to form a p-type doped region in the donor wafer. For example, as shown in FIG. 2, p-type dopants may be added to the donor wafer 102 to form p-type doped regions 202. The p-type dopants may include aluminum dopants implanted into a silicon carbide donor wafer. The activation may be performed at high temperatures, such as approximately 1700° C., to electrically activate the implanted dopants.

At block 1004, the method 1000 includes implanting hydrogen adjacent to a top surface of the donor wafer. For example, as shown in FIG. 2, the hydrogen 104 may be implanted adjacent to the top surface 106 of the donor wafer 102. The hydrogen implantation may be performed using ion implantation techniques at a controlled depth below the top surface 106 to create a weakened plane within the donor wafer crystal structure, for example 50-3000 nm.

At block 1006, the method 1000 includes bonding the donor wafer to a poly-aluminum nitride (poly-AlN) or semi-insulating silicon carbide (SiC) handle wafer with one or more dielectric layers disposed therebetween to form a bonded structure, where the implanted hydrogen is adjacent to the one or more dielectric layers. For example, as shown in FIG. 2, the donor wafer 102 may be bonded to the handle wafer 108 through engineered dielectric layers 116 comprising silicon dioxide (SiO₂) and/or silicon nitride (SiN). The poly-AlN handle wafer 108 may include a CTE-matched core 110 that provides a coefficient of thermal expansion similar to an AlN or GaN buffer layer, such as the bottom buffer layer 302 of FIG. 3, that will subsequently be grown on the semiconductor device.

At block 1008, the method 1000 includes annealing the bonded structure to remove a portion of the donor wafer, thereby forming a semiconductor layer disposed over the one or more dielectric layers. For example, as shown in FIG. 2, a portion of the donor wafer 102 of the bonded structure 112 is removed to form the semiconductor device 206. The annealing process may cause the hydrogen-implanted region 104 to expand and create microcracks along the implanted plane, resulting in exfoliation of the bulk donor wafer material. This smart cut process leaves only a thin semiconductor layer 204 of the original material of the donor wafer 102 (such as silicon carbide) bonded to the poly-AlN handle wafer 108. The resulting engineered substrate, namely the semiconductor device 206, combines the lattice matching benefits of the donor wafer 102 with the CTE matching advantages of the poly-AlN handle wafer 108. The resulting semiconductor layer 204 may have a thickness determined by the original hydrogen implantation depth and may provide an optimal surface for subsequent epitaxial growth of AlN or AlGaN buffer layers.

In some examples, the method 1000 includes forming a transistor device over the semiconductor layer, where the transistor device comprises an aluminum nitride (AlN) buffer layer, and where a coefficient of thermal expansion of the handle wafer is similar to a coefficient of thermal expansion of the AlN buffer layer to prevent wafer bowing during growth of the AlN buffer layer. For example, as shown in FIG. 3, the transistor device 300 may be formed over the semiconductor device 206 with a bottom buffer layer 302 comprising aluminum nitride (AlN) or aluminum gallium nitride (AlGaN). The poly-AlN handle wafer 108 includes a CTE-matched core 110 that provides coefficient of thermal expansion similar to the AlN buffer layer (within 15%) to prevent wafer bowing during high-temperature growth processes.

In some examples, the method 1000 includes positioning the p-type dopants such that they do not reach a surface of the semiconductor layer after exfoliation. The depth of the p-type implant is optimized using optimal conditions for implant dose, implant energy and implant activation annealing temperature. For example, as shown in FIG. 4, the p-type dopants of the p-type doped regions 202 are positioned so as to not reach a top surface 402 of the semiconductor layer 204 after removal of the excess donor wafer. There is a distance D between a top 404 of the p-type doped region 202 and the top surface 402 of the semiconductor layer 204.

In some examples, the method 1000 includes forming a high voltage GaN or AlGaN transistor over the semiconductor layer. For example, as shown in FIG. 3, the transistor device 300 may be configured as a high-voltage GaN or AlGaN field-effect transistor where drain fields of the transistor device penetrate through the semiconductor layer to improve field handling. The thin semiconductor layer 204 enables field penetration while maintaining the lattice matching advantages of the engineered substrate.

In some examples, the method 1000 includes modifying an interface between the semiconductor layer and the one or more dielectric layers using a process selected from plasma nitridation, plasma oxidation, or annealing in nitric oxide or nitrous oxide. For example, as shown in FIG. 8, the interface 400 between the semiconductor layer 204 and the dielectric layers 116 may be modified to optimize the SiC/SiO₂ interface on the handle wafer 108. The interface modification may be performed using plasma nitridation, plasma oxidation, or annealing in nitric oxide (NO) or nitrous oxide (N₂O) to reduce trapping at the backside and improve device performance and reliability.

In some examples, the method 1000 includes forming a backside superjunction device by including a doped p-type region in the semiconductor layer, where the donor wafer is SiC. For example, as shown in FIG. 5, the p-type doped regions 202 may be configured to form a superjunction backside field plate 502 in the semiconductor layer 204. The superjunction is configured to deplete during normal operation of the transistor device, with a density of p-type dopants in the p-type implanted region substantially matched to a density of electrons in the 2DEG of the buried channel.

In some examples, the method 1000 includes forming a gallium nitride buffer layer over the semiconductor layer. For example, as shown in FIG. 6, the bottom buffer layer 302 may comprise a gallium nitride buffer layer formed over the semiconductor layer 204. The GaN buffer layer may be a thin buffer layer that may optionally be p-type doped.

In some examples, the method 1000 includes forming a first transistor device over the semiconductor layer and forming a second transistor device over the semiconductor layer. For example, as shown in FIG. 7, a first transistor device 700 and a second transistor device 702 may be formed laterally adjacent to one another over the semiconductor layer 204 and monolithically integrated over the semiconductor device 206. The first and second transistor devices may share the bottom buffer layer 302 and be laterally separated by an isolation barrier 704.

In some examples, the method 1000 the donor wafer is SiC, the first transistor device includes a two-dimensional electron gas channel, and the second transistor device does not include a two-dimensional electron gas channel. For example, as shown in FIG. 9, the first transistor device 700 may include one or more 2DEG channels (such as the buried first 2DEG channel 308 and/or the topside second 2DEG channel 314), while the second transistor device 900 may be implemented without any 2DEG channels. In this mixed architecture, both SiC and GaN devices may be monolithically integrated on the same die, enabling hybrid device functionality on the engineered substrate.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A method of forming a semiconductor device, comprising:
implanting p-type dopants into a donor wafer and activating the p-type dopants to form a p-type doped region in the donor wafer;
implanting hydrogen adjacent to a top surface of the donor wafer;
bonding the donor wafer to a poly-aluminum nitride (poly-AlN) or semi-insulating silicon carbide (SiC) handle wafer with one or more dielectric layers disposed therebetween to form a bonded structure, wherein the implanted hydrogen is adjacent to the one or more dielectric layers; and
annealing the bonded structure to remove a portion of the donor wafer, thereby forming a semiconductor layer disposed over the one or more dielectric layers.

2. The method of claim 1, further comprising:
forming a transistor device over the semiconductor layer, the transistor device comprising an aluminum nitride (AlN) buffer layer,
wherein a coefficient of thermal expansion of the handle wafer is similar to a coefficient of thermal expansion of the AlN buffer layer to prevent wafer bowing during growth of the AlN buffer layer.

3. The method of claim 2, wherein implanting the p-type dopants into the donor wafer comprises:
positioning the p-type dopants such that they do not reach a surface of the semiconductor layer after exfoliation.

4. The method of claim 1, further comprising:
forming a high voltage GaN or AlGaN transistor over the semiconductor layer.

5. The method of claim 1, further comprising:
modifying an interface between the semiconductor layer and the one or more dielectric layers using a process selected from plasma nitridation, plasma oxidation, or annealing in nitric oxide or nitrous oxide.

6. The method of claim 1, wherein the donor wafer is SiC, the method further comprising:
forming a backside superjunction device by including a doped p-type region in the semiconductor layer.

7. The method of claim 1, further comprising:
forming a gallium nitride buffer layer over the semiconductor layer.

8. The method of claim 2, wherein forming the transistor device over the semiconductor layer includes forming a first transistor device over the semiconductor layer, the method comprising:
forming a second transistor device over the semiconductor layer.

9. The method of claim 8, wherein the donor wafer is SiC, wherein the first transistor device includes a two-dimensional electron gas channel, and wherein the second transistor device does not include a two-dimensional electron gas channel.

10. A semiconductor device comprising:
an engineered substrate comprising:
a poly-aluminum nitride (poly-AlN) or semi-insulating silicon carbide (SiC) handle wafer;
one or more dielectric layers disposed over the handle wafer; and
a semiconductor layer disposed over the one or more dielectric layers, wherein the semiconductor layer includes hydrogen implanted into a donor wafer, wherein the semiconductor layer is formed from a donor wafer bonded to the handle wafer, and wherein the donor wafer comprises silicon carbide (SiC) or sapphire; and
a transistor device formed over the engineered substrate, the transistor device comprising an aluminum nitride (AlN) buffer layer, wherein a coefficient of thermal expansion (CTE) of the handle wafer is similar to a CTE of the AlN buffer layer to prevent wafer bowing during growth of the AlN buffer layer.

11. The semiconductor device of claim 10, wherein the donor wafer comprises silicon carbide (SiC), and wherein the semiconductor layer comprises a SiC layer, and wherein the SiC layer comprises a p-type doped region.

12. The semiconductor device of claim 11, wherein the p-type doped region does not extend to a surface of the semiconductor layer.

13. The semiconductor device of claim 10, comprising:
a high voltage GaN or AlGaN transistor formed over the semiconductor layer.

14. The semiconductor device of claim 10, wherein the donor wafer is SiC, the semiconductor device further comprising:
a backside superjunction device including a lightly doped p-type region in the semiconductor layer.

15. The semiconductor device of claim 14, further comprising:
a gallium nitride buffer layer formed over the semiconductor layer.

16. The semiconductor device of claim 10, wherein the transistor device includes a first transistor device, the semiconductor device further comprising:
a second transistor device formed over the semiconductor layer.

17. The semiconductor device of claim 16, wherein the donor wafer is SiC, wherein the first transistor device includes a two-dimensional electron gas channel, and wherein the second transistor device does not include a two-dimensional electron gas channel.

18. A method of forming a semiconductor device, comprising:
implanting p-type dopants into a donor wafer and activating the p-type dopants to form a p-type doped region in the donor wafer;
implanting hydrogen adjacent to a top surface of the donor wafer;
bonding the donor wafer to a poly-aluminum nitride (poly-AlN) or semi-insulating silicon carbide (SiC) handle wafer with one or more dielectric layers disposed therebetween to form a bonded structure, wherein the implanted hydrogen is adjacent to the one or more dielectric layers;
annealing the bonded structure to remove a portion of the donor wafer, thereby forming a semiconductor layer disposed over the one or more dielectric layers; and
forming a transistor device over the semiconductor layer, the transistor device comprising an aluminum nitride (AlN) buffer layer,
wherein the transistor device includes a two-dimensional electron gas channel, and
wherein a coefficient of thermal expansion of the handle wafer is similar to a coefficient of thermal expansion of the AlN buffer layer to prevent wafer bowing during growth of the AlN buffer layer.

19. The method of claim 18, wherein forming the transistor device over the semiconductor layer includes forming a first transistor device over the semiconductor layer, the method comprising:
forming a second transistor device over the semiconductor layer.

20. The method of claim 19, wherein the first transistor device includes the two-dimensional electron gas channel, and wherein the second transistor device does not include a two-dimensional electron gas channel.
